(19) United States
(12) Patent Application Publication
(10) Pub. No.: US 2012/0132280 A1
(43) Pub. Date: May 31, 2012

(54) PHOTOCELL MODULE AND FABRICATION METHOD FOR PHOTOCELL MODULE

(75) Inventors: Yasunori Nagano, Kanagawa (JP); Tetsuya Komine, Kanagawa (JP); Masahiro Morooka, Kanagawa (JP); Harumi Takada, Kanagawa (JP)

(73) Assignee: Sony Corporation, Tokyo (JP)

(21) Appl. No.: 13/388,719

(22) PCT Filed: Aug. 12, 2010
(86) PCT No.: PCT/JP2010/063955

§ 371 Date: Feb. 3, 2012

(30) Foreign Application Priority Data
Aug. 21, 2009 (JP) 2009-192351

(51) Int. Cl. H01L 31/0203; H01L 31/18

(52) U.S. Cl. 136/259; 438/64; 257/E31.117

(57) ABSTRACT

The present invention can simplify a process.

In the present invention, a transparent conductive layer (5) is provided on an electrode side substrate (12); a porous semiconductor layer (7) is provided on the transparent conductive layer (5); and a counter electrode layer (9) in a state in which it is separated from the porous semiconductor layer (7) is provided. A cell partition wall (6) which is provided on the electrode side substrate (12) and surrounds the periphery of the porous semiconductor layer (7) is provided. In the sensitized solar cell module (11), electrolytic solution (10) is impregnated in the porous semiconductor layer (7) and the counter electrode layer (9), and a sealing material in the form of liquid is disposed in such a manner as to cover an upper portion of the cell partition wall (6) to seal the electrolytic solution (10). Then, the sealing material in the form of liquid is solidified.

### TECHNICAL FIELD

The present invention relates to a photocell module and a fabrication method for a photocell module, and is suitably applied, for example, to a sensitized solar cell module.

### BACKGROUND ART

Conventionally, a sensitized solar cell module to which photo-induced electron transfer sensitized by a dye is applied has been proposed. The sensitized solar cell module is a wet type cell module wherein electrolytic solution is filled in cells. As the sensitized solar cell module, a module having a monolithic structure in which all electrodes are formed on one substrate is known (for example, refer to Patent Document 1).

In the sensitized solar cell module having a monolithic structure, as shown in FIG. 1, it is common to form cells between two substrates (an electrode side glass substrate 2 and a cover glass substrate 3) and fill up the inside of the cells with electrolytic solution.

Since the material and fabrication cost of the sensitized solar cell module having a monolithic structure is low, implementation as a solar cell in the next generation is expected.

### PRIOR ART DOCUMENT

### Patent Document

Patent Document 1: Japanese Patent Laid-Open No. 2004-171827
Patent Document 2: Japanese Patent Laid-Open No. 2007-200796

### SUMMARY OF INVENTION

Incidentally, in the sensitized solar cell module of such a configuration as described above, a method that electrolytic solution is filled from a fine hole perforated in vacuum cells after two substrates are pasted and the cells are separated from each other is commonly used. In this manner, since, in the sensitized solar cell module, it is necessary to place, after cells are formed, the inside of the cells into a vacuum state and fill electrolytic solution into the cells, there is a problem that the fabrication process is complicated.

The present invention has been made taking the forgoing points into consideration and contemplates proposal of a photocell module which can simplify a process and a fabrication method for the photocell module.

In order to solve such a subject as described above, a photocell module according to the present invention includes a transparent substrate, a transparent conductive layer provided on the transparent substrate, a porous semiconductor layer provided on the transparent conductive layer, a counter electrode layer provided in a separated relationship from the porous semiconductor layer, electrolytic solution impregnated in the porous semiconductor layer and the counter electrode layer, a cell partition wall provided on the transparent substrate and surrounding the periphery of the porous semiconductor layer and the counter electrode layer, and a sealing compound layer disposed in a state of a material in the form of liquid so as to cover the cell partition wall on the opposite side to the transparent substrate to seal the electrolytic solution, the material in the form of liquid being solidified.

Consequently, in the photocell module, the electrolytic solution can be sealed in the cells by disposing, after the electrolytic solution is filled into the space in the cells formed from the cell partition wall and the transparent substrate, the material in the form of liquid so as to cover the cell partition wall and then solidify the material in the form of liquid.

A fabrication method for a photocell module according to the present invention includes a transparent conductive layer formation step of providing a transparent conductive layer on a transparent substrate, a porous semiconductor layer formation step of providing a porous semiconductor layer on the transparent conductive layer, a counter electrode layer and cell partition wall formation step of providing a counter electrode layer in a separated state from the porous semiconductor layer and providing a cell partition wall provided on the transparent substrate and surrounding the periphery of the porous semiconductor layer, an electrolytic solution impregnation step of impregnating electrolytic solution into the porous semiconductor layer and the counter electrode layer, a liquid resin disposition step of disposing a liquid material so as to cover the cell partition wall on the opposite side to the transparent substrate to seal the electrolytic solution, and a solidification step of solidifying the liquid material.

Consequently, in the fabrication method for a photocell module, the electrolytic solution can be sealed in the cells by disposing, after the electrolytic solution is filled into the space in the cells formed from the cell partition wall and the transparent substrate, the material in the form of liquid so as to cover the cell partition wall and then solidify the material in the form of liquid.

According to the present invention, the electrolytic solution can be sealed in the cells by disposing, after the electrolytic solution is filled into the space in the cells formed from the cell partition wall and the transparent substrate, the material in the form of liquid so as to cover the cell partition wall and then solidify the material in the form of liquid. Thus, with the present invention, a photocell module which can simplify a process and a fabrication method for the photocell module can be implemented.

### BRIEF DESCRIPTION OF DRAWINGS

FIG. 1 is a schematic diagrammatic view showing a configuration of a conventional sensitized solar cell module.

FIG. 2 is a schematic diagrammatic view showing a configuration of a sensitized solar cell module according to the present embodiment.

FIG. 3 is a flow chart illustrating a fabrication method.

FIG. 4 is a schematic diagrammatic view illustrating formation of an electrode.

FIG. 5 is a schematic diagrammatic view illustrating formation of a cell partition wall.

FIG. 6 is a schematic diagrammatic view illustrating filling of electrolytic liquid.

FIG. 7 is a schematic diagrammatic view illustrating filling of liquid state sealing compound.

FIG. 8 is a schematic diagrammatic view showing a configuration of a sensitized solar cell module according to another embodiment.

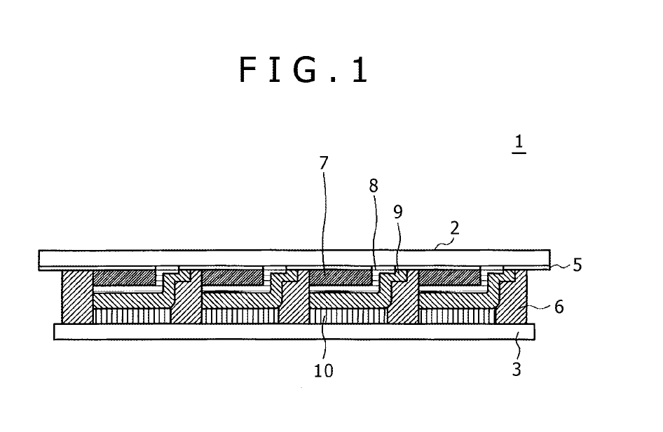

### MODE FOR CARRYING OUT THE INVENTION

In the following, an embodiment of the present invention is described in detail with reference to the drawings. It is to be noted that the description is given in the following order.

### 1. Embodiment

### 2. Other Embodiments

### 1. Embodiment

### [1-1. Configuration of the Sensitized Solar Cell]

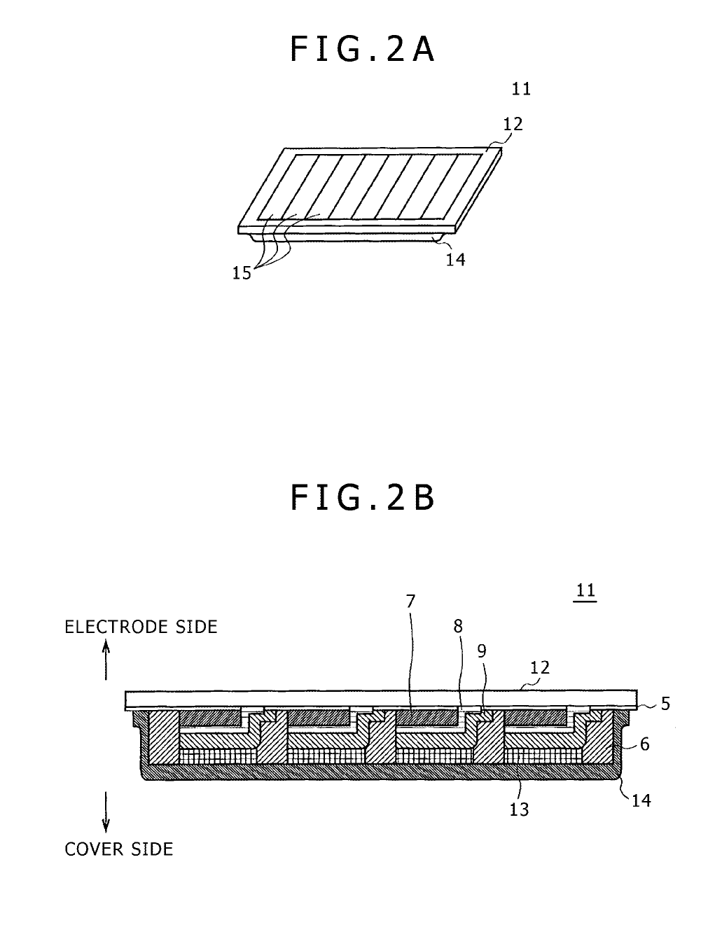

Referring to FIG. 2, reference numeral 11 generally indicates a sensitized solar cell module, and like elements to those of the conventional configuration are denoted by like reference numerals.

The sensitized solar cell module 11 is configured by forming eight cells connected in series to each other between an electrode side substrate 12 and a cover film 14. In FIG. 2(B), a sectional view of the sensitized solar cell module 11 is shown. It is to be noted that only four cells are shown in FIG. 2(B) for the convenience of illustration. This similarly applies also to the drawings succeeding FIG. 2(B), and, while only four cells are shown in the sectional view, the eight cells are disposed actually.

The sensitized solar cell module 11 includes the electrode side substrate 12, a transparent conductive layer 5, a cell partition wall 6, a porous semiconductor layer 7, a porous insulating layer 8, a counter electrode layer 9, electrolytic solution 10 (not shown), a sealing compound layer 13 and the cover film 14. It is to be noted that the electrolytic solution 10 is placed in a state in which it is impregnated in the porous semiconductor layer 7, porous insulating layer 8 and counter electrode layer 9.

Light enters through the electrode side substrate 12. The light passes through the electrode side substrate 12 and the transparent conductive layer 5 and is irradiated on the porous semiconductor layer 7. The porous semiconductor layer 7 absorbs the light and is ionized to emit electrons. The emitted electrons are transmitted to the transparent conductive layer 5.

On the other hand, the transparent conductive layer 5 supplies electrons to the electrolytic solution 10 through the counter electrode layer 9. The electrolytic solution 10 accepts the electrons by a reduction reaction. Here, the electrolytic solution 10 is impregnated in the porous semiconductor layer 7, porous insulating layer 8 and counter electrode layer 9. Therefore, the electrolytic solution 10 supplies the accepted electrons to the porous semiconductor layer 7. As a result, the porous semiconductor layer 7 can accept the electrodes and return to a normal state in which the it is not ionized.

In particular, the sensitized solar cell module 11 can function as a cell which can generate current in response to light and in which the counter electrode 9 functions as the positive electrode and the transparent conductive layer 5 functions as the negative electrode.

The electrode side substrate 12 may be configured from any material only if it passes light having a wavelength used for photoelectric conversion with a high transmittance therethrough and has electric insulation, and, for example, glass, resin or the like is used for the electrode side substrate 12. In most cases, glass is used for the electrode side substrate 12 because it has high thermal resistance. In the case where a resin is used, it is preferable to use a material which is superior in thermal resistance and transparency such as a polycarbonate resin, an epoxy resin or the like.

The transparent conductive layer 5 is formed on the electrode side substrate 12 and is patterned so as to connect the cells 15 in series. The transparent conductive layer 5 may be formed from a material which passes light of a wavelength used for the photoelectric conversion at a high transmission rate therethrough and has electric conductivity, and tin oxide or indium oxide is used suitably. Further, by doping other atoms, it is possible to improve the conductivity of the transparent conductive layer 5. As the atoms to be doped, fluorine, antimony or the like is available for tin oxide, and tin or the like is available for indium oxide.

In particular, for the transparent conductive layer 5, indium-tin composite oxide (ITO), tin oxide (IV) doped with fluorine (FTO), tin oxide (IV), zinc oxide (II), indium-zinc composite oxide (IZO) and so forth are used.

The porous semiconductor layer 7 is provided adjacent to the transparent conductive layer 5. For the porous semiconductor layer 7, semiconductor fine particles of an n-type metal oxide such as titanium dioxide, zinc oxide, tungsten oxide, niobium oxide, strontium titanate or zinc oxide, a material having a Perovskite structure and so forth are used suitably. As the material of the porous semiconductor layer 7, titanium dioxide of the anatase type is particularly preferable.

Preferably, the semiconductor fine particles have sensitizing dye absorbed thereto in order to assure a high photoelectric conversion efficiency. Although the sensitizing dye is not limited particularly, an organic dye, a metal complex and so forth are used suitably, and from terms of performance, a ruthenium-based metal complex is used particularly suitably.

The porous insulating layer 8 is provided adjacent to the porous semiconductor layer 7 and the counter electrode layer 9 and separates and isolates the porous semiconductor layer 7 and the counter electrode layer 9 from each other. Preferably, the porous insulating layer 8 diffuses and reflects light incident thereto through the electrode side substrate 12. This is because it is intended to improve the absorption factor of light by the porous semiconductor layer 7.

For the porous insulating layer 8, a known material having electric insulation can be used, and for example, fine particles of silicon dioxide, rutile titanium dioxide, aluminum oxide, zirconium dioxide and so forth are used suitably.

For the counter electrode layer 9, a known material having conductivity can be used. A material for the counter electrode layer 9 preferably has electric stability, and platinum, gold, carbon, conductive polymer and so forth are used suitably. Preferably, the counter electrode layer 9 has a large surface area in order to promote a reduction reaction of an electrolyte.

The electrolytic solution 10 is solution including a redox agent (a redox). Although there is no limitation to the redox agent, for example, a combination of an iodide and a metal or an iodide salt of an organic matter, a combination of bromine and a metal or an iodide salt of an organic matter or the like is used.

The electrolytic solution 10 is in the form of liquid or gel. From a point of view of prevention of liquid leakage, electrolytic solution in the form of gel is used preferably. Although there is no particular limitation to a method for the gelation of electrolytic solution, it is particularly preferable for a fibrous inorganic matrix material to retain the electrolytic solution. This is because a small amount of inorganic matrix material can retain a greater amount of electrolytic solution and it is possible to suppress the internal resistance which appears by addition of a matrix material and prevent a drop of the photoelectric efficiency.

This inorganic matrix material is prepared by dispersing powder of an inorganic material (for example, titanium dioxide) into potassium hydroxide solution and drying the solution after a hydrothermal reaction occurs in an autoclave. Further, an inorganic matrix material is added to electrolytic solution having a redox agent dissolved therein and is dispersed by an ultrasonic wave process or the like to prepare the electrolytic solution 10 (refer to Patent Document 2).

Preferably, the electrolytic solution 10 only has an amount by which it is impregnated into the porous semiconductor layer 7, porous insulating layer 8 and counter electrode layer 9 and does not form a layer consisting only of the electrolytic solution 10. This is because it is intended to maintain a good characteristic of the sealing compound layer 13.

The cell partition wall 6 surrounds the periphery of the porous semiconductor layer 7, porous insulating layer 8 and counter electrode layer 9 and separates the cells 15 from each other. In other words, the cell partition wall 6 configures an outer periphery of the cells 15. The cell partition wall 6 is formed higher by a thickness substantially equal to the thickness of the sealing compound layer 13 than the height of the counter electrode layer 9 and cooperates with the sealing compound layer 13 to seal the cells 15.

As the partition wall material for the cell partition wall 6, known materials having electric insulation can be used. Specifically, various resin materials are used suitably. In particular, for example, an ultraviolet curing type resin which cures in response to ultraviolet rays, a two-liquid curing type resin which begins to cure after it is mixed with curing agent, a thermosetting type resin which cures by heating, a hot melt resin which liquefies at a high temperature, a low-melting point glass frit and so forth are used suitably. For the cell partition wall 6, an ultraviolet curing type resin or a two-liquid curing type resin is particularly preferable. This is because there is no necessity to apply heat to a sensitizing dye after absorption.

As the resin material, various resin materials such as, for example, an epoxy resin, an urethane resin, a silicone resin, a polyester resin, a phenol resin, an urethane resin and an amino resin can be used. Since the resin material contacts with the electrolytic solution 10, a material having high chemical resistance to the electrolytic solution 10 is used suitably.

The sealing compound layer 13 covers the cover side of the cell partition wall 6 to seal the electrolytic solution 10 in the cells 15. In other words, the sealing compound layer 13 cooperates with the cell partition wall 6 to surround the cells 15 and cover the cells 15. Preferably, the sealing compound layer 13 contacts with the counter electrode layer 9. In other words, preferably a layer of the electrolytic solution 10 is not formed between the counter electrode layer 9 and the sealing compound layer 13. This is because, if the electrolytic solution 10 contacts with the sealing compound layer 13 in the state of liquid before solidification (the sealing compound layer in the state is hereinafter referred to as liquid state sealing material), then this obstructs solidification of the liquid state sealing material and has a bad influence on a characteristic as the sealing compound layer 13.

The sealing compound layer 13 is a solidified substance of the liquid state sealing material. For the liquid state sealing material, a known material having electric insulation can be used, and various materials having a nature of solidifying after applied in the state of liquid can be used. For example, an ultraviolet curing type resin which cures in response to ultraviolet rays, a two-liquid curing type resin which begins to cure after it is mixed with curing agent, a thermosetting type resin which cures by heating, a hot melt resin which liquefies at a high temperature, a low-melting point glass frit and so forth are used suitably as the liquid state sealing material.

In the case where an ultraviolet curing type resin is used as the liquid state sealing material, the liquid state sealing material is solidified by irradiation of ultraviolet rays. In the case where a two-liquid curing type resin is used as the liquid state sealing material, the liquid state sealing material is solidified by leaving the same for a predetermined period of time (for example, several minutes to several hours) at a room temperature. In the case where a thermosetting type resin is used as the liquid state sealing material, the liquid state material is solidified by heating the same for a predetermined period of time at a predetermined heating temperature (for example, 80 [° C.] to 200 [° C.]) by an oven or the like. A hot melt resin and a glass frit are liquefied in a heated state and used as a liquid state material. After the liquid state sealing material is applied, it is solidified by being cooled.

For the liquid state sealing material, curing of an ultraviolet curing type resin and a two-liquid curing type resin is particularly preferable. This is because there is little necessity to apply heat upon curing and there is no necessity to apply heat to the electrolytic solution 10. As this resin material, a resin material having low moisture permeability is preferable in order to prevent evaporation of the electrolytic solution 10. Various resin materials such as, for example, an epoxy resin, an urethane resin, a silicone resin, a polyester resin, a phenol resin, an urethane resin and an amino resin can be used.

The cover film 14 is provided in order to protect the cells 15, and has a role of suppressing the influence of an external environment (particularly humidity) and blocks out the eight cells 15 connected in series from the outside. The cover film 14 is fixed to the electrode side substrate 12 at least by adhering the periphery of the eight cells 15 to the electrode side substrate 12 or the transparent conductive layer 5 or to both of them. There is no limitation to the adhering method, and for example, thermal laminate, a bonding agent and so forth can be used. Further, the cover film 14 may be adhered not only to the periphery of the cells 15 but also to the overall face of the cells 15 on the cover side.

Although the cover film 14 is not limited particularly, a film having low humidity permeability is used suitably. For example, a resin film of polyamide, an evaporated metal film, a laminate film wherein a metal foil and a resin film are laminated in advance and so forth are used suitably. Although there is no limitation to the thickness of the cover film 14, preferably a color film of a thickness greater than 20 [μm], particularly greater than 50 [μm], is used in order to lower the humidity permeability.

### [1-2. Fabrication Method]

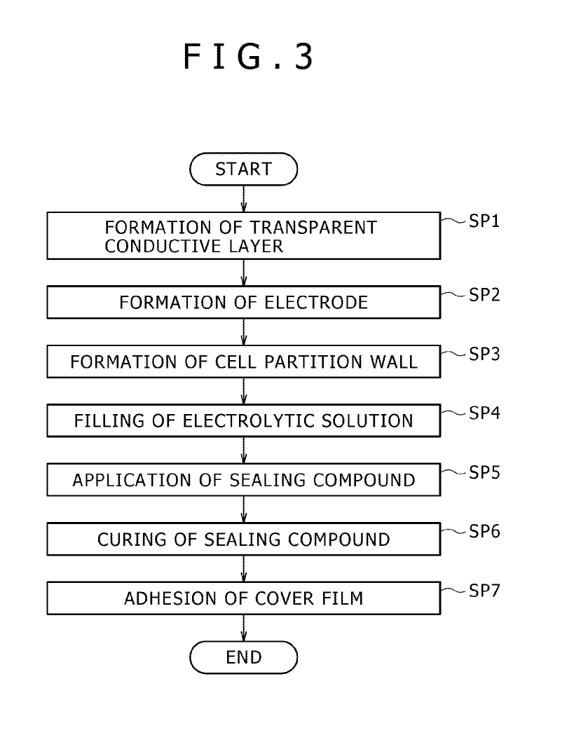

Now, a fabrication method of the sensitized solar cell module 11 is described with reference to a flow chart of FIG. 3.

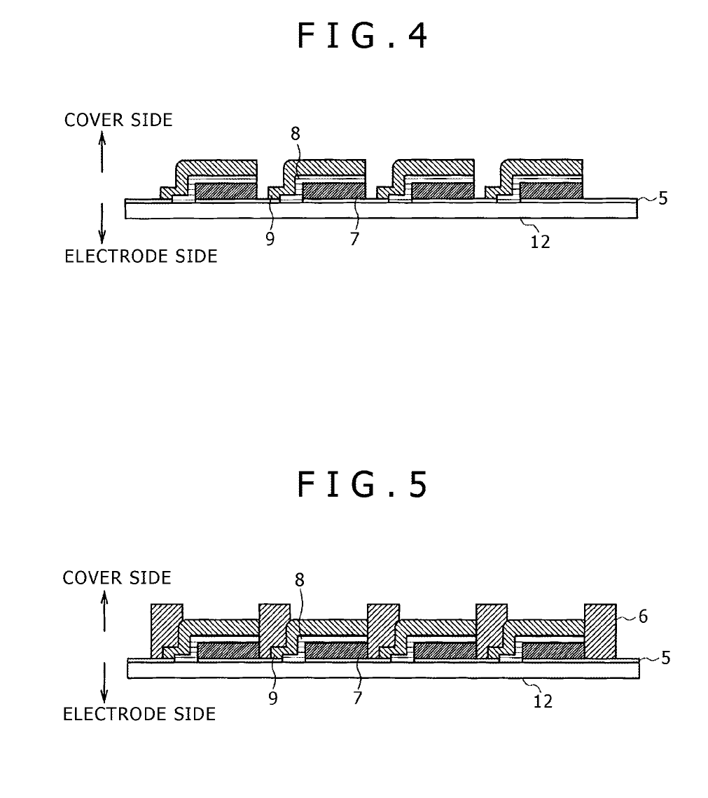

First, a transparent conductive layer 5 is formed on an electrode side substrate 12, for example, by a sputtering method, a vapor deposition method or the like as shown in FIG. 4 (step SP1). It is to be noted that, in FIGS. 4 to 7, the cover side is shown on the upper side of the space and the upward and downward direction is inverted from that in FIG. 2 for the convenience of illustration.

Then, electrodes (a porous semiconductor layer 7, a porous insulating layer 8 and an counter electrode layer 9) are formed on the transparent conductive layer 5 (step SP2). The porous semiconductor layer 7 is formed by applying a porous semiconductor material in the form of slurry, for example, by silk screen printing, lithography or the like and then sintering the porous semiconductor material by heating.

Then, a porous insulating layer 8 and an counter electrode layer 9 are successively formed on the porous semiconductor layer 7. The porous insulating layer 8 and the counter electrode layer 9 are formed similarly to the porous semiconductor layer 7. Then, the electrode side substrate 12 is impregnated with solution of a sensitizing dye to absorb the dye, and after excessive sensitizing dye is removed, the electrode side substrate 12 is dried.

A cell partition wall 6 is formed so as to separate the cells 15 from one another as shown in FIG. 5 (step SP3). The cell partition wall 6 is formed by applying a partition wall material in the form of liquid, for example, by a dispenser, screen printing, lithography or the like and then solidifying the partition wall material.

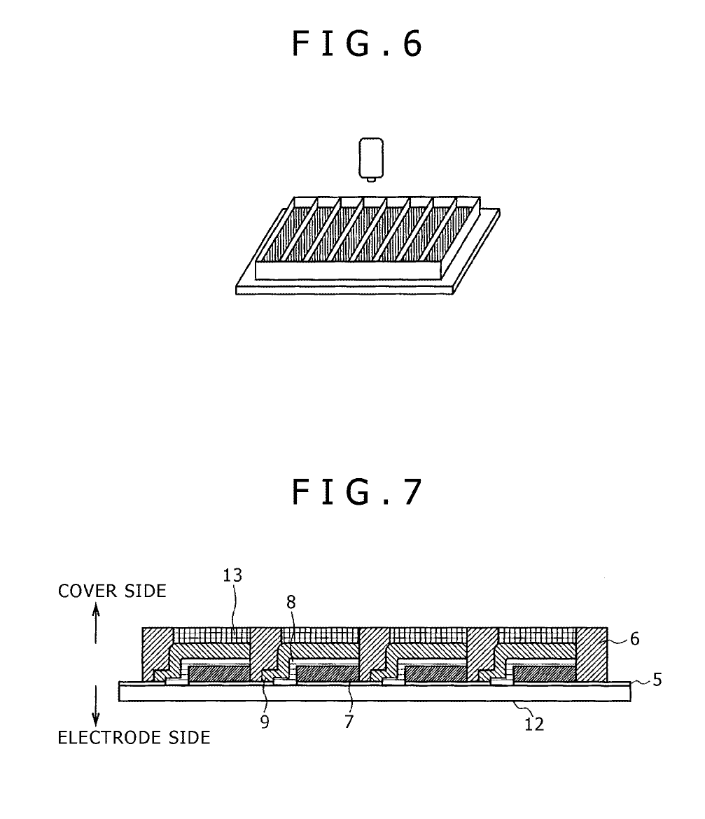

Then, electrolytic solution 10 is filled into the cells 15 as shown in FIG. 6 (step SP4). In the case where electrolytic solution in the form of liquid of low viscosity is used as the electrolytic solution 10 and the electrolytic solution 10 is simply filled by a dispenser, for example, the electrolytic solution 10 spreads through the inside of the cells 15 by surface tension or a capillary phenomenon, and the porous semiconductor layer 7, porous insulating layer 8 and counter electrode layer 9 are impregnated with the electrolytic solution 10.

In the case where electrolytic solution in the form of gel is used as the electrolytic solution 10, after the electrolytic solution 10 is filled into the cells 15 by a dispenser, for example, the electrolytic solution 10 spreads through the inside of the cells 15 by surface tension, a capillary phenomenon or the like, and the porous semiconductor layer 7, porous insulating layer 8 and counter electrode layer 9 are impregnated with the electrolytic solution 10. Further, the electrolytic solution 10 may be impregnated into the porous semiconductor layer 7, porous insulating layer 8 and counter electrode layer 9 by placing the electrolytic solution 10 on the counter electrode layer 9 and then pushing the electrolytic solution 10 into the inside of the counter electrode layer 9 by a spatula or the like. In order to promote infiltration of the electrolytic solution 10 into the inside of the cells 15, a vibration process, an ultrasonic process or the like may be executed for the electrolytic solution 10.

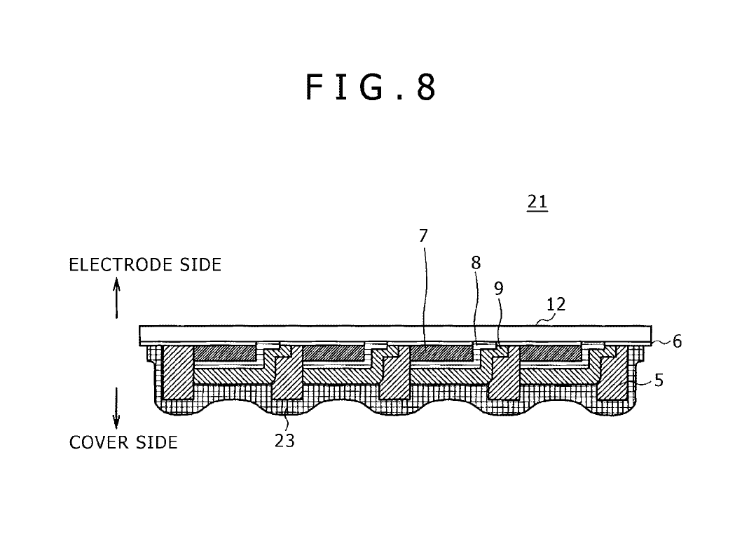

A sealing material in the form of liquid is applied to the counter electrode layer 9 as shown in FIG. 7 (step SP5). There is no limitation to the application method, and an application method is selected suitably in accordance with a characteristic of the sealing material in the form of liquid. In the case where the sealing material in the form of liquid has comparatively high viscosity (10,000 [Pa·s] or more at 10 [rpm]), an amount of the sealing material in the form of liquid which fills up the inside of the cells 15 (from the surface of the counter electrode layer 9 to an upper face of the cell partition wall 6) is applied, for example, by a dispenser. Further, after the sealing material in the form of liquid is applied by an excessive amount, the excessive sealing material in the form of liquid may be removed using a squeegee. Also it is possible to use such a method as, for example, silk screen printing or lithography.

In the case where the sealing material in the form of liquid has comparatively low viscosity (lower than 10,000 [Pa·s] at 10 [rpm]), if the sealing material in the form of liquid is applied, for example, by a dispenser, silk screen printing, lithography or the like, then the surface on the cover side is leveled by the gravity.

Then, the sealing material in the form of liquid is solidified in accordance with a characteristic of the sealing material in the form of liquid to form a sealing compound layer 13 (step SP6).

Finally, a cover film 14 is adhered to the electrode side substrate 12 to cover the cells 15 with the cover film 14 (step SP7). At this time, the space between the cover film 14 and the cells 15 may be placed into a vacuum state, for example, by vacuuming.

In this manner, the sensitized solar cell module 11 is provided with the sealing compound layer 13 by providing the cell partition wall 6 which surrounds the porous semiconductor layer 7, porous insulating layer 8 and counter electrode layer 9, filling the electrolytic solution 10 into them, covering the cover side of the cell partition wall 6 with the sealing material in the form of liquid and then solidifying the sealing material in the form of liquid.

Consequently, in the sensitized solar cell module 11, the electrolytic solution 10 may be filled into the cell partition wall 6 which is open large to the cover side. Therefore, with the sensitized solar cell module 11, the process of filling the electrolytic solution 10 can be simplified very much in comparison with a conventional method wherein the electrolytic solution 10 is injected through a small hole perforated in a cell after the cell is intentionally formed such that the internal space thereof has a sealed state.

### [1-3. Operation and Effect]

In the configuration described above, the sensitized solar cell module 11 has an electrode side substrate 12 as a transparent substrate, a transparent conductive layer 5 provided on the electrode side substrate 12, a porous semiconductor layer 7 provided on the transparent conductive layer 5, and a counter electrode layer 9 provided in an separated relationship from the porous semiconductor layer 7 with a porous insulating layer 8 interposed therebetween. The sensitized solar cell module 11 has electrolytic solution 10 impregnated in the porous semiconductor layer 7 and the counter electrode layer 9, and a cell partition wall 6 provided on the electrode side substrate 12 and surrounding the periphery of the porous semiconductor layer 7 and the counter electrode layer 9. Further, the sensitized solar cell module 11 has a sealing compound layer 13 which is in a state of a material in the form of liquid (sealing material in the form of liquid) and is disposed so as to cover the cover side of the cell partition wall 6 which is the opposite side to the electrode side substrate 12 to seal the electrolytic solution 10 and formed by solidification of the sealing material in the form of liquid.

Consequently, since the sensitized solar cell module 11 can be formed by covering, after the electrolytic solution 10 is filled, the cell partition wall 6 using a sealing material in the form of liquid having high flexibility to seal the electrolytic solution 10, the process of filling the electrolytic solution 10 can be simplified.

Here, in the cells 15, preferably no air is admitted into the inside of the cells 15 to the utmost in order to improve the environmental resistance to a heat cycle and so forth. For example, in the case where the cells 15 are sealed using a solid-state film and a bonding agent, the bonding agent must be hardened while the cell partition wall 6, counter electrode layer 9 and film are joined fully under the vacuum, and the process is complicated. Further, in this instance, since it is necessary to deform the film, a state in which fixed stress is normally applied is established, and a state in which the film is likely to be exfoliated is entered.

In contrast, in the sensitized solar cell module 11, by using a deformable sealing material in the form of liquid, the sealing material in the form of liquid can be applied reasonably by a single step. Since the applied sealing material in the form of liquid is solidified in this manner, the cells 15 can be sealed stably while stress by deformation is not applied thereto.

Meanwhile, in the sensitization type solar cell disclosed in Patent Document 1, since no cell partition wall is provided, the electrolytic solution must be retained by the electrodes, and the risk of liquid leakage of the electrolytic solution by high heat or vibration cannot be avoided. Further, it is necessary to solidify the electrolytic solution to a state proximate to the solid, and the photoelectric conversion efficiency is dropped by increase of the internal resistance.

In contrast, in the sensitized solar cell module 11, since the cells 15 are sealed by the electrode side substrate 12, cell partition wall 6 and sealing compound layer 13, the risk of liquid leakage is low, and for the electrolytic solution 10, electrolytic solution can be selected freely among those from that in the form of liquid to that in the form of gel. Thus, high photoelectric conversion efficiency can be maintained.

The sealing compound layer 13 is formed from an ultraviolet curing type resin or a two-liquid curing type resin. Consequently, since the necessity for the heating step after filling of the electrolytic solution 10 can be eliminated, the electrolytic solution 10 need not be heated, and a characteristic degradation and so forth by heating of the electrolytic solution can be prevented.

The sealing compound layer 13 is held in contact with the counter electrode layer 9. Consequently, since the sealing material in the form of liquid little contacts with the electrolytic solution 10, inhibition of the curing reaction of the sealing material in the form of liquid by the electrolytic solution 10 and characteristic deterioration by the inhibition can be suppressed.

The electrolytic solution 10 has a form of gel. Consequently, in comparison with a case in which the electrolytic solution 10 is solution of low viscosity, liquid leakage of the electrolytic solution 10 from a small gap or the like can be prevented effectively.

The electrolytic solution 10 is held by a fibrous inorganic matrix. Consequently, the electrolytic solution 10 can maintain the internal fluidity thereof to some degree by gelation of the electrolytic solution 10 only by a small amount of the inorganic matrix, and the drop of the photoelectric conversion efficiency by the gelation can be suppressed to the utmost.

The cell partition wall 6 is formed from a resin. Consequently, in comparison with a case in which an inorganic material is used, the necessity for high temperature heating by sintering or melting can be eliminated.

The porous semiconductor layer 7 has a sensitizing dye absorbed therein, and the cell partition wall 6 is formed from an ultraviolet curing type resin or a two-liquid curing type resin.

Consequently, a heating step need not be carried out after absorption of the sensitizing dye, and characteristic deterioration by heating of the sensitizing dye can be prevented.

The sensitized solar cell module 11 further has a cover film 14 which is adhered to the electrode side substrate 12 or the transparent conductive layer 5 and covers the cells 15 each having the porous semiconductor layer 7, counter electrode layer 9, electrolytic solution 10, cell partition wall 6 and sealing compound layer 13.

Consequently, in the sensitized solar cell module 11, the cells 15 can be sealed by the electrode side substrate 12 and the cover film 14, and therefore, the influence of humidity and so forth from an external environment can be reduced and the durability can be improved.

With the configuration described above, in the sensitized solar cell module 11, the transparent conductive layer 5 is provided on the electrode side substrate 12; the porous semiconductor layer 7 is provided on the transparent conductive layer 5; the counter electrode layer 9 in the state in which it is separated from the porous semiconductor layer 7 is provided; and the cell partition wall 6 which is provided on the electrode side substrate 12 and surrounds the periphery of the porous semiconductor layer 7 is provided. In the sensitized solar cell module 11, the electrolytic solution 10 is impregnated in the porous semiconductor layer 7 and the counter electrode layer 9, and a sealing material in the form of liquid is disposed in such a manner as to cover the upper portion of the cell partition wall 6 to seal the electrolytic solution 10 and then the sealing material in the form of liquid is solidified.

Consequently, in the sensitized solar cell module 11, the electrolytic solution 10 can be filled by a simple and easy process only of filling the electrolytic solution 10 into the inside of the cell partition wall 6 which is open greatly on the cover side thereof. Thus, the present invention can implement a photocell module which can be fabricated by a simplified process and a fabrication method for the photocell module.

### 2. Other Embodiments

It is to be noted that the embodiment described above is directed to the case in which the sensitized solar cell module 11 has the cover film 14. The present invention is not limited to this, and the cover film 14 is not necessarily required, for example, as in the case of a sensitized solar cell module 21 shown in FIG. 8.

Further, the embodiment described hereinabove is directed to the case in which the sealing compound layer 13 is formed in such a manner as to embed protruding portions of the cell partition wall 6 from the counter electrode layer 9. The present invention is not limited to this, but a sealing compound layer 23 may be formed in such a manner as to cover the counter electrode layer 9 and the cell partition wall 6 from the cover side, for example, as in the case of a sensitized solar cell module 21 shown in FIG. 8. In this instance, the cell partition wall 6 need not project from the counter electrode layer 9 but may be formed so as to have a substantially equal height. This sealing compound layer 23 is formed by various coating methods such as, for example, dye coating. Although, in FIG. 8, the sealing compound layer 23 is provided to the periphery of the eight cells 15, the sealing compound layer 23 may cover at least the cover side of the cell partition wall 6 but need not be formed to the periphery of the eight cells 15.

Consequently, since the sealing resin in the form of liquid is not filled for each of the cells 15 but it can be applied for each sensitized solar cell module 21, the process can be simplified.

Further, though not particularly mentioned in the foregoing description of the embodiment, for example, the compatibility of the electrolytic solution 10 and the sealing material in the form of liquid is made very low and the viscosity of the sealing material in the form of liquid is made low (for example, 500 [Pa·s] or less at 10 [rpm]). Consequently, it is possible to prevent the electrolytic solution 10 and the sealing material in the form of liquid from mixing with each other without admitting the air into the space between the electrolytic solution 10 and the sealing material in the form of liquid. Further, since the sealing material in the form of liquid spreads along the electrolytic solution 10, the electrolytic solution 10 can be sealed simply, easily and with certainty.

Further, the embodiment described hereinabove is directed to the case in which the counter electrode layer 9 and the sealing compound layer 13 contact with each other. The present invention is not limited to this, but the counter electrode layer 9 and the sealing compound layer 13 do not necessarily contact with each other. For example, if a material whose solidification is not obstructed by the electrolytic solution 10 is used for the sealing compound layer 13, then even if a layer of the electrolytic solution 10 is formed, there is no problem. Also it is possible to form, between the electrolytic solution 10 and the sealing compound layer 13, a separating layer for separating them from each other. For the separating layer, liquid, a film or the like can be used.

Further, the embodiment described hereinabove is directed to the case in which the porous semiconductor layer 7 and the counter electrode layer 9 are separated from each other by the porous insulating layer 8. The present invention is not limited to this, but only it is necessary to separate the porous semiconductor layer 7 and the counter electrode layer 9 from each other and the porous insulating layer 8 is not necessarily required.

Further, the embodiment described hereinabove is directed to the case in which the porous semiconductor layer 7, porous insulating layer 8 and counter electrode layer 9 are formed by sintering a substance in the form of slurry after it is applied. The present invention is not limited to this, and the substance in the form of slurry need not necessarily be sintered. In the case where the porous insulating layer 8 and the counter electrode layer 9 can be formed by a drying step within a range within which the sensitizing dye is not destroyed, the porous insulating layer 8 and the counter electrode layer 9 may be formed after the sensitizing dye is absorbed by the porous semiconductor layer 7. Further, in this instance, the porous insulating layer 8 and the counter electrode layer 9 may be formed after the cell partition wall 6 is formed.

Furthermore, the embodiment described hereinabove is directed to the case in which the photocell module is a sensitized solar cell wherein a sensitizing dye is absorbed by the porous semiconductor layer 7. The present invention is not limited to this, but the sensitizing dye need not necessarily be absorbed, and the present invention can be applied to all photocell modules of the wet type.

Further, the embodiment described hereinabove is directed to the case in which the sensitized solar cell module 11 as a photocell module is configured from the electrode side substrate 12 as a transparent substrate, transparent conductive layer 5 as a transparent conductor layer, porous semiconductor layer 7 as a porous semiconductor layer, counter electrode layer 9 as a counter electrode layer, electrolytic solution 10 as electrolytic solution, cell partition wall 6 as a cell partition wall, and sealing compound layer 13 as a sealing compound layer. The present invention is not limited to this, but a photocell module of the present invention may be configured from a transparent substrate, a transparent conductor layer, a porous semiconductor layer, a counter electrode layer, electrolytic solution, a cell partition wall and a sealing compound layer.

### INDUSTRIAL APPLICABILITY

The present invention can be utilized for a photocell module which is incorporated, for example, in various electronic apparatus.

### DESCRIPTION OF REFERENCE NUMERALS

1, 11, 21 . . . Sensitized solar cell module, 5 . . . Transparent conductive layer, 6 . . . Cell partition wall, 7 . . . Porous semiconductor layer, 8 . . . Porous insulating layer, 9 . . . Counter electrode layer, 10 . . . Electrolytic solution, 12 . . . Electrode side substrate, 13, 23 . . . Sealing compound layer, 14 . . . Cover film, 15 . . . Cell

1. A photocell module, comprising:
a transparent substrate;
a transparent conductive layer provided on said transparent substrate;
a porous semiconductor layer provided on said transparent conductive layer;
a counter electrode layer provided in a separated relationship from said porous semiconductor layer;
electrolytic solution impregnated in said porous semiconductor layer and said counter electrode layer;
a cell partition wall provided on said transparent substrate and surrounding a periphery of said porous semiconductor layer and said counter electrode layer; and
a sealing layer disposed in a state of a material in a form of liquid so as to cover said cell partition wall on a opposite side to said transparent substrate to seal said electrolytic solution, the material in a form of liquid being solidified.

2. The photocell module according to claim 1, wherein said sealing layer is configured from an ultraviolet curing type resin or a two-liquid hardening type resin.

3. The photocell module according to claim 2, wherein said sealing layer contacts with said counter electrode layer.

4. The photocell module according to claim 3, wherein said electrolytic solution is in a form of gel.

5. The photocell module according to claim 4, wherein said electrolytic solution is retained by a fibrous inorganic matrix.

6. The photocell module according to claim 5, wherein said cell partition wall is configured from a resin.

7. The photocell module according to claim 6, wherein
said porous semiconductor layer has a sensitizing dye absorbed thereto; and
said cell partition wall is configured from an ultraviolet curing type resin or a two-liquid hardening type resin.

8. The photocell module according to claim 7, further comprising:
a cover film adhered to said transparent substrate or said transparent conductive layer and covering cells having said porous semiconductor layer, counter electrode layer, electrolytic solution, cell partition wall and sealing layer.

9. A fabrication method for a photocell module, comprising:
a transparent conductive layer formation step of providing a transparent conductive layer on a transparent substrate;
a porous semiconductor layer formation step of providing a porous semiconductor layer on the transparent conductive layer;
a counter electrode layer and cell partition wall formation step of providing a counter electrode layer in a separated state from the porous semiconductor layer and providing a cell partition wall provided on the transparent substrate and surrounding a periphery of the porous semiconductor layer;
an electrolytic solution impregnation step of impregnating electrolytic solution into the porous semiconductor layer and the counter electrode layer;
a liquid resin disposition step of disposing a liquid material so as to cover the cell partition wall on an opposite side to the transparent substrate to seal the electrolytic solution; and
a solidification step of solidifying the liquid material.
